(19) United States
(12) Patent Application Publication
(10) Pub. No.: US 2007/0057295 A1
(43) Pub. Date: Mar. 15, 2007

(54) Substrate bonding method and apparatus

(76) Inventors: Ji Yong Lee, Yongin-si (KR); You Min Cha, Yongin-si (KR); Hee Cheol Kang, Yongin-si (KR)

Correspondence Address: Robert E. Bushnell, Suite 300, 1522 K Street, N.W., Washington, DC, 20005, US

(21) Appl. No.: 11/498,776

(22) Filed: Aug. 4, 2006

(30) Foreign Application Priority Data
Sep. 9, 2005 (KR) 2005-84208

(51) Int. Cl. H01L 31/113

(52) U.S. Cl. 257/290

(57) ABSTRACT

A substrate bonding apparatus and a substrate bonding method apply pressure according to the size of upper and lower substrates when the upper and lower substrates are bonded. The apparatus includes: an upper pressing unit having an upper plate to press an upper substrate, and a first presser to drive the upper plate to press the upper substrate; and a lower pressing unit placed under the upper pressing unit and having a lower plate that supports a lower substrate to be affixed to the upper substrate and presses the lower substrate, and a second presser to drive the lower plate to press the lower substrate. The apparatus can be used in bonding various-sized substrates, e.g., when relatively large-sized substrates are bonded, a lower substrate is pressed upward without causing sagging of an upper substrate, and when relatively small-sized substrates are bonded, an upper substrate is pressed with gas.

### CLAIM OF PRIORITY

This application makes reference to, incorporates the same herein, and claims all benefits accruing under 35 U.S.C. § 119 from an application for SUBSTRATE BONDING DEVICE AND THE SUBSTRATE BONDING METHOD USING IT earlier filed in the Korean Intellectual Property Office on Sep. 9, 2005 and there duly assigned Serial No. 10-2005-0084208.

### BACKGROUND OF THE INVENTION

1. Field of the Invention

The present invention relates to a substrate bonding method and apparatus, and more particularly, to a substrate bonding method and apparatus in which pressure is applied according to the size of upper and lower substrates upon the upper and lower substrates being bonded.

2. Description of the Related Art

In general, flat panel displays are classified as inorganic displays or organic displays according to the materials used in their manufacture. Inorganic displays includes Plasma Display Panels (PDPs) using Photo Luminescence (PL), Field Emission Displays (FEDs) using Cathode Luminescence (CE), etc. Furthermore, organic displays include Liquid Crystal Displays (LCDs), Organic Light Emitting Displays (OLEDs), etc.

OLEDs are classified as small molecule OLEDs using a single molecule of a low molecular weight and polymer OLEDs using a polymer of a high molecular weight. OLEDs have a response time about 30,000 times shorter than currently used LCDs, so that they can display a moving picture. Furthermore, OLEDs can emit light by themselves, so that they can have a wide viewing angle and achieve a high brightness. Thus, OLEDs have attracted attention as next-generation displays.

An OLED generally includes an anode, an organic layer, and a cathode, which are formed on a glass substrate in sequence. A glass substrate is transparent so as to transmit light emitted from the OLED. On the glass substrate, an anode, an organic layer and a cathode are formed in sequence.

The anode is a positive electrode to supply holes to the organic layer, and is formed as a transparent Indium Tin Oxide (ITO) layer in order to transmit the light.

The organic layer includes a hole injecting layer, a hole transport layer, an electron transport layer and an electron injecting layer, in which holes from the anode and electrons from the cathode are recombined to generate light of a predetermined color.

The cathode is a negative electrode to supply the electrons, and is made of metal having a low work function in order to smoothly supply the electrons.

An encapsulating plate seals the OLED. The encapsulating plate is internally provided with a hygroscopic material to absorb moisture.

Furthermore, an ultra violet (UV) hardening resin affixes the edge of the encapsulating plate 140 to the glass substrate, thereby preventing external air and moisture from permeating into the OLED.

In the OLED with this configuration, when a positive voltage is supplied to the anode and a negative voltage is supplied to the cathode, the anode supplies the holes to the organic layer and the cathode supplies the electrons to the organic layer.

The holes and the electrons are recombined in the organic layer to generate light of a predetermined color. The generated light is emitted to the outside through the anode formed of the transparent ITO layer and the transparent electrode.

In fabricating such an OLED, the glass substrate and the encapsulating plate are bonded together by a separate bonding apparatus. Bonding can be achieved by pressing the glass substrate placed above the encapsulating plate by a gas such as nitrogen.

However, this bonding method is not adapted to a large-sized OLED as the size of the OLED becomes large on demand.

That is, when the glass substrate is pressed toward the encapsulating plate, the center of the glass substrate having no supporting structure sags, so that an organic material grown as a film is likely to directly contact the encapsulating plate, thereby damaging the organic material.

The OLED is provided with a plurality of pixels, which includes an OLED formed on a glass substrate, and a Thin Film Transistor (TFT) to drive the OLED. Such an OLED is susceptible to water, so that a sealing structure has been proposed for waterproofing, in which a deposition substrate is covered with a metal cap coated with a desiccant agent or a sealing glass substrate. In this sealing structure, a sealing process is performed by applying a load of a flat plate to a device glass substrate formed with the OLED and the sealing glass substrate or applying a uniform pressure of N₂ to an entire surface thereof.

In a chamber for fabricating an OLED, an adhering process for a first substrate and a second substrate and a hardening process for a sealant using Ultra Violet (UV) rays are performed at the same time.

First, the first substrate is vacuum-adhered to a metallic suction plate opposite to a transmissible film, and the second substrate is put on the transmissible film. At this time, an OLED formed in a predetermined area of the first substrate is opposite to a desiccant agent layer formed in a predetermined area of the second substrate.

Then, a transferring unit moves down the suction plate, and the transferring unit is pressed until the first substrate and the second substrate are spaced apart from each other by a predetermined gap, thereby applying a load to the suction plate or applying a uniform pressure to an entire surface of the suction plate.

Then, a UV emitter provided in the outside of the chamber emits UV rays to a sealant through the transmissible film and the second substrate. Therefore, the sealant is hardened, so that the first substrate and the second substrate are adhered to each other.

In the substrate sealing method described above, the transmissible film used in a process of hardening the sealant must endure the pressure of the adhering process and have high transmissivity of UV. Quartz, tempered glass, and hardened plastics can be used as the transmissible film satisfying these conditions.

However, when the OLED using a large-sized substrate is in the adhering process, it is difficult to fabricate the transmissible film maintaining rigidity to endure the pressure, thereby limiting the adhering process of the large-sized substrate.

### SUMMARY OF THE INVENTION

Accordingly, it is an aspect of the present invention to provide to a substrate bonding apparatus and a substrate bonding method using the same, which can be used in bonding various-sized substrates, e.g., when relatively large-sized substrates are bonded, a lower substrate is pressed upward without sagging an upper substrate, and when relatively small-sized substrates are bonded, a upper substrate is pressed with gas.

In an exemplary embodiment of the present invention, a substrate bonding apparatus includes: an upper pressing unit having an upper plate adapted to press an upper substrate, and a first presser adapted to drive the upper plate to press the upper substrate; and a lower pressing unit arranged under the upper pressing unit and having a lower plate adapted to support and to press a lower substrate to be affixed to the upper substrate, and a second presser adapted to drive the lower plate to press the lower substrate.

The upper pressing unit preferably includes a vacuum suction unit adapted to support the upper substrate on a top of the upper substrate.

The first presser preferably uses pressure based on gas injection. The second presser preferably includes an elastic member, a supporting plate adapted to support the elastic member, and a pressing member adapted to press the supporting plate.

The elastic member preferably includes one of either a spring or a damper.

The pressing member preferably uses pressure based on gas injection.

The second presser preferably uses pressure based on gas injection.

The substrate bonding apparatus preferably further includes a substrate size determiner adapted to determine sizes of the upper and lower substrates introduced into the substrate bonding apparatus.

In another exemplary embodiment of the present invention, a substrate bonding method includes: introducing an upper substrate and a lower substrate into a substrate bonding apparatus; determining sizes of the upper and lower substrates; and performing a pressing operation in consideration of the determined sizes of the upper and lower substrates.

The pressing operation preferably includes one of either an upper pressing operation or a lower pressing operation.

The substrate bonding method preferably further includes setting a reference size for at least one of the upper and lower substrates before determining the sizes of the upper and lower substrates.

The pressing operation preferably includes performing the upper pressing operation upon a determination that the upper and lower substrates are smaller than the reference size. The pressing operation alternatively preferably includes performing the lower pressing operation upon a determination that the upper and lower substrates are larger than the reference size.

### BRIEF DESCRIPTION OF THE DRAWINGS

A more complete appreciation of the present invention and many of the attendant advantages thereof will be readily apparent as the present invention becomes better understood by reference to the following detailed description when considered in conjunction with the accompanying drawings in which like reference symbols indicate the same or similar components, wherein:

FIG. 1 is a sectional view of a structure of an OLED;

FIG. 2 is a schematic view of substrates being bonded by pressing an upper substrate;

FIG. 3 is a schematic view of an upper substrate sagging when large-sized substrates are bonded by pressing the upper substrate;

FIG. 4 is a sectional view of a substrate bonding apparatus according to an embodiment of the present invention;

FIG. 5 is a schematic view of an upper substrate pressed by an upper pressing unit of FIG. 4;

FIG. 6 is a schematic view of a lower substrate pressed by a lower pressing unit of FIG. 4;

FIG. 7 is a plan view, a perspective view and a sectional view of the lower pressing unit of FIG. 4;

FIG. 8 is a sectional view of a substrate bonding apparatus according to another embodiment of FIG. 6;

FIG. 9 is a sectional view of the substrate bonding apparatus using a pressing member of a lower pressing unit according to another embodiment present invention; and

FIG. 10 is a sectional view of the substrate bonding apparatus according to still another embodiment of FIG. 6.

### DETAILED DESCRIPTION OF THE INVENTION

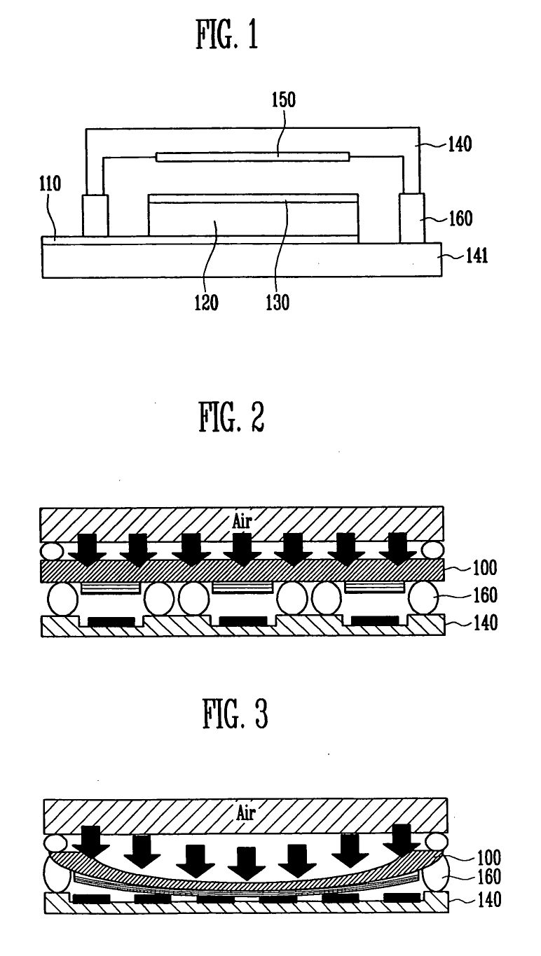

FIG. 1 is a sectional view of an OLED. A glass substrate 100 is transparent so as to transmit light emitted from the OLED.

On the glass substrate 100, an anode 110, an organic layer 120 and a cathode 130 are formed in sequence.

The anode 110 is a positive electrode to supply holes to the organic layer 120, and is formed as a transparent Indium Tin Oxide (ITO) layer in order to transmit the light.

The organic layer 120 includes a hole injecting layer, a hole transport layer, an electron transport layer and an electron injecting layer, in which holes from the anode 110 and electrons from the cathode 130 are recombined to generate light of a predetermined color.

The cathode 130 is a negative electrode to supply the electrons, and is made of metal having a low work function in order to smoothly supply the electrons.

An encapsulating plate 140 seals the OLED. The encapsulating plate 140 is internally provided with a hygroscopic material 150 to absorb moisture.

Furthermore, an ultra violet (UV) hardening resin 160 affixes the edge of the encapsulating plate 140 to the glass substrate 100, thereby preventing external air and moisture from permeating into the OLED.

In the OLED with this configuration, when a positive voltage is supplied to the anode 110 and a negative voltage is supplied to the cathode 130, the anode 110 supplies the holes to the organic layer 120 and the cathode 130 supplies the electrons to the organic layer 120.

The holes and the electrons are recombined in the organic layer 120 to generate light of a predetermined color. The generated light is emitted to the outside through the anode 110 formed of the transparent ITO layer and the transparent electrode 100.

In fabricating such an OLED, the glass substrate 100 and the encapsulating plate 140 are bonded together by a separate bonding apparatus. As shown in FIG. 2, bonding can be achieved by pressing the glass substrate 100 placed above the encapsulating plate 140 by a gas such as nitrogen.

However, this bonding method is not adapted to a large-sized OLED as the size of the OLED becomes large on demand.

That is, as shown in FIG. 3, when the glass substrate 100 is pressed toward the encapsulating plate 140, the center of the glass substrate 110 having no supporting structure sags, so that an organic material grown as a film is likely to directly contact the encapsulating plate 140, thereby damaging the organic material.

An OLED is provided with a plurality of pixels, which includes an OLED formed on a glass substrate, and a Thin Film Transistor (TFT) to drive the OLED. Such an OLED is susceptible to water, so that a sealing structure has been proposed for waterproofing, in which a deposition substrate is covered with a metal cap coated with a desiccant agent or a sealing glass substrate. In this sealing structure, a sealing process is performed by applying a load of a flat plate to a device glass substrate formed with the OLED and the sealing glass substrate or applying a uniform pressure of N₂ to an entire surface thereof.

FIG. 1 is a view of an OLED fabricated in a chamber.

Referring to FIG. 1, in a chamber (not shown) for fabricating an OLED, an adhering process for a first substrate 10 and a second substrate 20 and a hardening process for a sealant using ultra violet (UV) rays are performed at the same time.

First, the first substrate 10 is vacuum-adhered to a metallic suction plate 40 opposite to a transmissible film 30, and the second substrate 20 is put on the transmissible film 30. At this time, an OLED 11 formed in a predetermined area of the first substrate 10 is opposite to a desiccant agent layer 12 formed in a predetermined area of the second substrate 20.

Then, a transferring unit (not shown) moves down the suction plate 40, and the transferring unit is pressed until the first substrate 10 and the second substrate 20 are spaced apart from each other by a predetermined gap, thereby applying a load to the suction plate 40 or applying a uniform pressure of N₂ to an entire surface of the suction plate 40.

Then, a UV emitter 50 provided in the outside of the chamber (not shown) emits UV rays to a sealant 15 through the transmissible film 30 and the second substrate 20. Therefore, the sealant 15 is hardened, so that the first substrate 10 and the second substrate 20 are adhered to each other.

In the substrate sealing method described above, the transmissible film 30 used in a process of hardening the sealant 15 should endure the pressure of the adhering process and have high transmissivity of UV. Quartz, tempered glass, and hardened plastics can be used as the transmissible film 30 satisfying these conditions.

However, in the case where the OLED using a large-sized substrate is in the adhering process, it is difficult to fabricate the transmissible film 30 maintaining rigidity to endure the pressure, thereby limiting the adhering process of the large-sized substrate.

Hereinafter, exemplary embodiments of the present invention are described with reference to accompanying drawings.

FIG. 4 is a sectional view of a substrate bonding apparatus according to an embodiment of the present invention.

A substrate bonding apparatus 100 according to an embodiment of the present invention includes an upper pressing unit 200 having an upper plate 210 to press an upper substrate 100; and a presser to drive the upper plate 210 to press the upper substrate 100, and a lower pressing unit 400 placed under the upper pressing unit 200 and having a lower plate 410 that supports a lower substrate 140 to be coupled with the upper substrate 100 and presses the lower substrate 140, and a presser to drive the lower plate 410 to press the lower substrate 140.

The upper pressing unit 200 and the lower pressing unit 400 are placed in a chamber 310, and a bonding process is performed in the chamber 310. In one side of the chamber 310, a hardening beam emitter 330 is provided to perform a hardening process while the upper and lower substrates 100 and 140 are bonded. The hardening beam emitter 330 penetrates the chamber 310 and is configured to emit a beam to a corresponding part of the lower substrate 140.

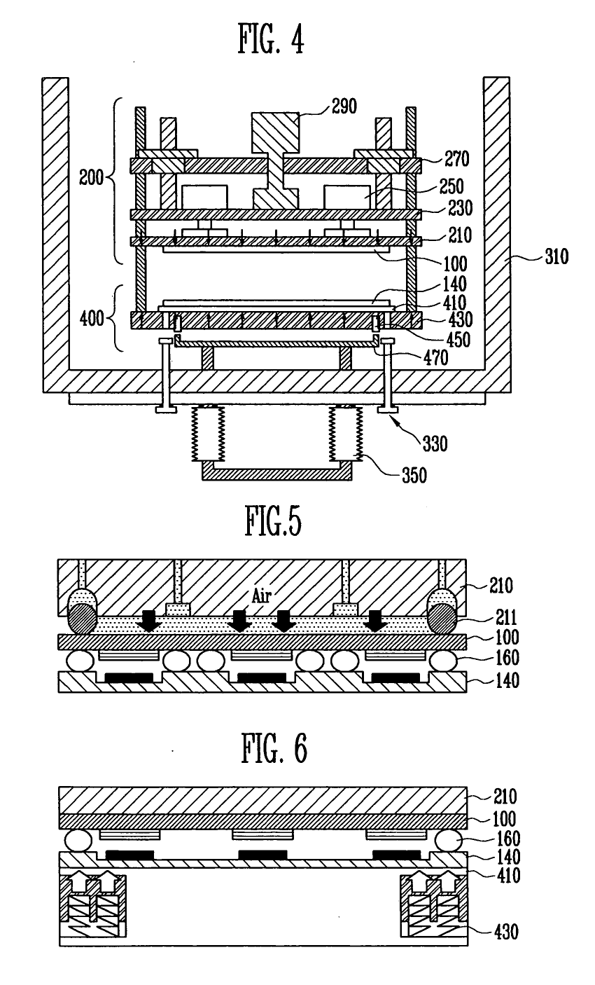

FIG. 5 is a schematic view illustrating that an upper substrate is pressed by the upper pressing unit of FIG. 4.

The upper pressing unit 200 includes the upper plate 210 to press the upper substrate 100. The upper plate 210 is provided with a vacuum suction means (not shown) to support the upper substrate 100. In more detail, the vacuum suction means supports the upper substrate 100 on a surface of the upper substrate 100, in which the surface is not coated with an organic material and faces upward.

In the rear of the surface of the upper plate 210 supporting the upper substrate 100, a pneumatic cylinder 250 is provided to drive an auxiliary plate 230 to move close to and apart from the upper plate 210.

The upper plate 210 includes an O-ring 211 to form an airtight space between the upper substrate 100 and the upper plate 210 when the upper substrate 100 is vacuum-sucked or pressed by nitrogen gas.

Furthermore, the upper plate 210 is provided with the vacuum suction means connected thereto and a pneumatic means (not shown), which can be implemented by a general vacuum pump and a general gas control valve, respectively. Typically, nitrogen gas is used herein.

The auxiliary plate 230 is supported by the pneumatic cylinder 250, so that it can move linearly. The auxiliary plate 230 facilitates the upper plate 210 pressing the upper substrate 100. In the rear of the auxiliary plate 230, a gap control actuator 290 and a gap control guide 270 are provided to control a gap between the auxiliary plate 230 and the upper plate 210.

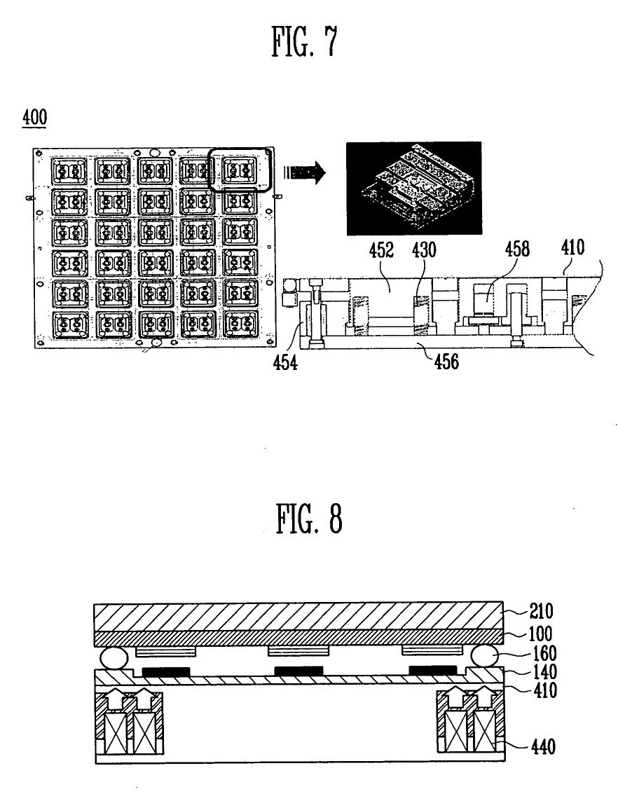

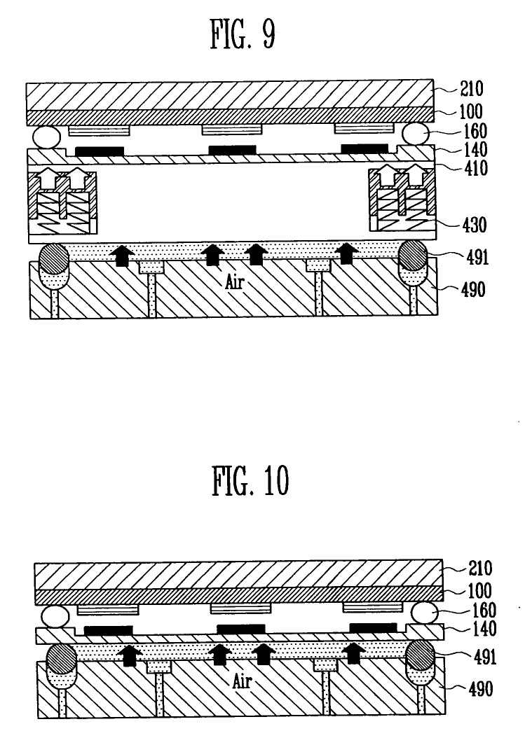

FIG.6 is a schematic view illustrating that a lower substrate is pressed by a lower pressing unit of FIG. 4, FIG. 7 shows a plan view, a perspective view and a sectional view of the lower pressing unit of FIG. 4, and FIG. 8 is a sectional view of a substrate bonding apparatus according to another embodiment of FIG. 6.

The lower pressing unit 400 includes the lower plate 410 to press the lower substrate 140. The lower plate 410 supports a surface of the lower substrate 140, in which the lower substrate 140 is supported on the lower plate 410 by its own weight. Here, the surface of the lower substrate 140 is the rear of a surface to be bonded with the upper substrate 100.

Behind the lower plate 410 is provided with a presser to drive the lower plate 410 to substantially press the lower substrate 140.

The presser includes an elastic member to absorb shock of the lower plate 410, a supporting plate 450 to support the elastic member, and a pressing member 470 pressing the supporting plate 450 so as to substantially press the lower plate 410.

Here, the elastic member can be implemented by a spring 430 (refer to FIG. 6), a damper 440 (refer to FIG. 8), or the like.

Referring to FIG. 6, the supporting plate 450 supports and accommodates the spring 430 therein. A pair of springs 430 is configured to press one pressing block 452. Furthermore, an intermediate plate 454 is provided between the pressing blocks 452. Also, the intermediate plate 454 is provided with a linear bush 458 for dividing a pressure cell into the pair of springs 430 and the pressing block 452.

The spring 430, the intermediate plate 454 and the linear bush 458 are supported and sealed up by the lower plate 356.

As shown in FIG. 7, the pressing block 452 together with the pair of springs 430 forms a single pressing cell. The pressing cell is plurally provided in the presser of the lower pressing unit 400, and thus uniformly applies the pressure to the whole surface of the lower substrate 140 having a rectangular shape.

In the rear surface of the supporting plate 450 accommodating the spring 430, the pressing member 470 is provided to substantially press the supporting plate 450. The pressing member 470 penetrates the chamber 310 and extends to the outside of the chamber 310. Furthermore, the pressing member 470 is provided with a bellows 350 (refer to FIG. 4) to seal up the chamber 310 as it is expanded and contracted.

As shown in FIG. 8, the lower pressing unit 400 can have a damper 440 instead of the spring 430 used in the embodiments shown in FIGS. 6 and 7. Here, the damper 440 is used as the elastic member and acts like the spring 430 of FIGS. 6 and 7. Therefore, repetitive descriptions will be avoided.

FIG. 9 is a sectional view of the substrate bonding apparatus using a pressing member of a lower pressing unit according to another embodiment present invention.

The lower plate 410 supports a surface of the lower substrate 140, in which the lower substrate 140 is supported on the lower plate 410 by its own weight. Here, the surface of the lower substrate 140 is the rear of a surface to be bonded with the upper substrate 100.

Behind the lower plate 410 is provided with a presser to drive the lower plate 410 to substantially press the lower substrate 140.

The presser includes an elastic member to absorb shock of the lower plate 410, a supporting plate 450 to support the elastic member, and a pressing member pressing the supporting plate 450 so as to substantially press the lower plate 410.

The pressing member is provided on the rear of the supporting plate 450 accommodating the elastic member such as the spring 430, the damper 440 or the like, thereby substantially pressing the supporting plate 450.

The pressing member can be implemented by a pneumatic system like the upper pressing unit 200, and includes a lower pressing plate 480.

The lower pressing plate 480 is provided with an O-ring 481 to form an airtight space between the lower pressing plate 480 and the lower plate 410 when the pressing is performed.

Furthermore, the lower pressing plate 480 is connected with a gas supplying means (not shown) that typically employs a gas control valve. In general, nitrogen gas is used. The gas supplying means penetrates the chamber 310 and extends to the outside of the chamber 310. Furthermore, the lower pressing plate 480 can be provided with a bellows (not shown) like that of FIG. 4 to seal up the chamber 310 as it is expanded and contracted.

FIG. 10 is a sectional view of the substrate bonding apparatus according to still another embodiment of FIG. 6.

The lower pressing unit 400 includes a lower pressing member 490 to press the lower substrate 140. The lower pressing member 490 supports a surface of the lower substrate 140, in which the lower substrate 140 is supported on the lower pressing member 490 by its own weight. Here, the surface of the lower substrate 140 is the rear of a surface to be bonded with the upper substrate 100.

The lower pressing member 490 injects gas toward the lower substrate 140, thereby substantially pressing the lower substrate 140.

The lower pressing member 490 can employ a pneumatic system like that used in the upper pressing unit 200.

The lower pressing member 490 is provided with an O-ring 491 to form an airtight space between the lower pressing member 490 and the lower substrate 140 when the pressing is performed.

Furthermore, the lower pressing member 490 is connected with a gas supplying means (not shown) that typically employs a gas control valve. In general, nitrogen gas is used. The gas supplying means penetrates the chamber 310 and extends to the outside of the chamber 310. Furthermore, the lower pressing member 490 can be provided with a bellows (not shown) like that of FIG. 4 to seal up the chamber 310 as it is expanded and contracted.

A substrate size determiner (not shown) can be provided in the inside or the outside of the chamber, thereby determining the sizes of the upper and lower substrates 100 and 140 introduced into the chamber 310 and boned to each other.

When the substrate size determiner is employed, either of the upper pressing unit 200 or the lower pressing unit 400 is used according to the size of the upper and lower substrates 100 and 140 introduced into the chamber 310, thereby bonding the upper and lower substrates 100 and 140 each other. A predetermined reference value of the substrate size has been previously inputted to the substrate size determiner. For example, when the substrate size determiner determines that a measured size of the substrate is smaller than the reference value, the upper pressing unit 200 is used. On the other hand, when the substrate size determiner determines that a measured size of the substrate is larger than the reference value, the lower pressing unit 400 is used.

Instead of the substrate size determiner, a worker may manually set whether the upper pressing unit 200 or the lower pressing unit 400 is to be used.

Furthermore, a substrate bonding method using the substrate bonding apparatus according to an embodiment of the present invention is as follows.

The substrate bonding method using the substrate bonding apparatus according to an embodiment of the present invention includes introducing the upper and lower substrates to the substrate bonding apparatus; determining the sizes of the upper and lower substrates; and pressing the upper and lower substrates according to the determined sizes of the upper and lower substrates.

When the upper and lower substrates are introduced into the substrate bonding apparatus, the size of at least one of the upper and lower substrates is determined. Because the upper and lower substrates used in a typical bonding process are equal in size to each other, the size of either of the upper or lower substrate is generally determined.

After the sizes of the upper and lower substrate are determined, either of upper pressing or lower pressing is performed according to the determined sizes of the upper and lower substrates. The upper pressing is performed when the upper and lower substrates are relatively small. On the other hand, the lower pressing is performed when the upper and lower substrates are relatively large. A reference for determining the size of the upper and lower substrate can be set by a worker on the basis of his/her experience.

Before determining the size of the substrates, a reference size setting process can be performed to set a reference size value of either of the upper or lower substrate. Also, the reference size value can be set by a worker on the basis of his/her experience. Thus, either of the upper pressing or the lower pressing is performed according to the set reference size value.

As described above, the present invention provides a substrate bonding apparatus and a substrate bonding method which can be used in bonding various-sized substrates, e.g., when relatively large-sized substrates are bonded, a lower substrate is pressed upward without an upper substrate sagging, and when relatively small-sized substrates are bonded, an upper substrate is pressed with gas.

Although exemplary embodiments of the present invention have been shown and described, modifications can be made to these embodiment without departing from the principles and spirit of the present invention, the scope of which is defined by the appended claims.

What is claimed is:

1. A substrate bonding apparatus comprising:
an upper pressing unit having an upper plate adapted to press an upper substrate, and a first presser adapted to drive the upper plate to press the upper substrate; and
a lower pressing unit arranged under the upper pressing unit and having a lower plate adapted to support and to press a lower substrate to be affixed to the upper substrate, and a second presser adapted to drive the lower plate to press the lower substrate.

2. The substrate bonding apparatus according to claim 1, wherein the upper pressing unit comprises a vacuum suction unit adapted to support the upper substrate on a top of the upper substrate.

3. The substrate bonding apparatus according to claim 1, wherein the first presser uses pressure based on gas injection.

4. The substrate bonding apparatus according to claim 1, wherein the second presser comprises an elastic member, a supporting plate adapted to support the elastic member, and a pressing member adapted to press the supporting plate.

5. The substrate bonding apparatus according to claim 4, wherein the elastic member comprises one of either a spring or a damper.

6. The substrate bonding apparatus according to claim 4, wherein the pressing member uses pressure based on gas injection.

7. The substrate bonding apparatus according to claim 1, wherein the second presser uses pressure based on gas injection.

8. The substrate bonding apparatus according to claim 1, further comprising a substrate size determiner adapted to determine sizes of the upper and lower substrates introduced into the substrate bonding apparatus.

9. A substrate bonding method comprising:
introducing an upper substrate and a lower substrate into a substrate bonding apparatus;
determining sizes of the upper and lower substrates; and
performing a pressing operation in consideration of the determined sizes of the upper and lower substrates.

10. The substrate bonding method according to claim 9, wherein the pressing operation comprises one of either an upper pressing operation or a lower pressing operation.

11. The substrate bonding method according to claim 9, further comprising setting a reference size for at least one of the upper and lower substrates before determining the sizes of the upper and lower substrates.

12. The substrate bonding method according to claim 11, wherein the pressing operation comprises performing the upper pressing operation upon a determination that the upper and lower substrates are smaller than the reference size.

13. The substrate bonding method according to claim 11, wherein the pressing operation comprises performing the lower pressing operation upon a determination that the upper and lower substrates are larger than the reference size.
